(19) United States
(12) Patent Application Publication
(10) Pub. No.: US 2025/0185264 A1
(43) Pub. Date: Jun. 5, 2025

(54) NOVEL EMBEDDED NANO POROUS CAPS

(71) Applicants: Applied Materials, Inc., Santa Clara, CA (US); The Florida International University Board of Trustees, Miami, FL (US)

(72) Inventors: Reshmi Banerjee, Miami, FL (US); Markondeyaraj Pulugurtha, Miami, FL (US); Mudit Sunilkumar Khasgiwala, Milpitas, CA (US); Meghna Maheshkumar Patel, Navsari (IN); Kunal Ghosh, Bengaluru (IN); Subramani Kengeri, Saratoga, CA (US); Sachin Jayant Patil, Bengaluru (IN); Arvin Khosravi, Los Gatos, CA (US)

(73) Assignees: Applied Materials, Inc., Santa Clara, CA (US); The Florida International University Board of Trustees, Miami, FL (US)

(21) Appl. No.: 18/525,406

(22) Filed: Nov. 30, 2023

(51) Int. Cl. H01G 4/008; H01G 4/08

(52) U.S. Cl. CPC H10D 1/696; H01G 4/008; H01G 4/08

(57) ABSTRACT

A capacitor may include a substrate may include a cavity. The capacitor may include a plurality of particles disposed within the cavity. The capacitor may include a first metal layer, deposited on the substrate, within the cavity, and on the plurality of particles. The capacitor may include a dielectric layer, deposited on the first metal layer. The capacitor may include a second metal layer, deposited on the dielectric layer. The capacitor may include a third metal layer, deposited on the second metal layer such that the cavity is substantially filled.

### TECHNICAL FIELD

The present technology relates to semiconductor systems, processes, and equipment. More specifically, the present technology relates to capacitors for use in semiconductors and other electronic devices.

### BACKGROUND

Capacitor performance is a crucial part of power delivery systems. As the operational bandwidth of processors and other devices increases (e.g., to 10 GHz), greater capacitive performance is required. As chips, packages, and other systems get smaller, the need for capacitors in smaller form factors grows, while still needed greater capacitive performance. Thus, there is a need for capacitors with a greater capacitive density as compared to the current technology.

### BRIEF SUMMARY

A capacitor may include a substrate may include a cavity. The capacitor may include a plurality of particles disposed within the cavity. The capacitor may include a first metal layer, deposited on the substrate, within the cavity, and on the plurality of particles. The capacitor may include a dielectric layer, deposited on the first metal layer. The capacitor may include a second metal layer, deposited on the dielectric layer. The capacitor may include a third metal layer, deposited on the second metal layer such that the cavity is substantially filled.

In some embodiments, the capacitor may include an epoxy layer deposited on the third metal layer and a via formed through the epoxy layer and in electrical contact with the first metal layer. In some embodiments, the dielectric layer may include at least one of hafnia, zirconia, hafnium silicate, alumina, silica, and hafnium zirconium oxide. The substrate may include a silicon-containing material. The plurality of particles may include at least one of silica, silicate glass particles, and barium titanate particles. The plurality of particles may form an electrode with a diameter of about 10 microns to about 10,000 microns. The plurality of particles may be fused to form a fused electrode that is 5 microns to 500 microns in thickness. The first metal layer and/or the second metal layer may include at least one of titanium nitride, ruthenium, ruthenium oxide, tungsten, platinum, and palladium.

A method of forming a capacitor may include providing a substrate. The method may include printing a plurality of particles on the substrate, the plurality of particles at least partially fused together. The method may include depositing a first metal layer on the substrate and the plurality of particles. The method may include depositing a dielectric layer on the first metal layer. The method may include depositing a second metal layer on the dielectric layer, such that the plurality of particles is planarized. The method may include depositing a current collector layer on the second metal layer.

In some embodiments, the method may include removing a portion of the dielectric layer and second metal layer. The method may include depositing an epoxy, such that the capacitor is planarized. The method may also include, forming a via such that the via is in electrical contact with at least one of the third metal layer and the first metal layer.

In some embodiments, the substrate may include a cavity and the plurality of particles may be disposed within the cavity. The method may include removing a portion of the dielectric layer and second metal layer. The method may include depositing an epoxy, such that the capacitor is planarized. The method may include forming a via such that the via is in electrical contact with at least one of the third metal layer and the first metal layer. The plurality of particles may include fiber-based particles. The current collector layer may include a paste including at least one of graphene and copper. The paste may include silver. The plurality of particles may include inorganic materials and a polymer coating. One or more of the first metal layer, the second metal layer, and the third metal layer may be formed via atomic layer deposition. The first metal layer and the second metal layer may include titanium nitride.

A capacitor may include a substrate. The capacitor may include a first metal layer. The capacitor may include a plurality of printed particles, disposed atop the first metal layer. The capacitor may include a dielectric layer disposed on the plurality of printed particles. The capacitor may include a second metal layer disposed on the dielectric layer. The capacitor may include a current collector disposed on the second metal layer.

In some embodiments, the capacitor may include an epoxy layer disposed on the second metal layer and a metal pathway extending from a top of the capacitor through the epoxy layer and in electrical contact with at least one of the current collector and the first metal layer. The substrate may include at least one of a silicon-containing material and a nickel-containing material.

### BRIEF DESCRIPTION OF THE DRAWINGS

FIG. 1 illustrates a flowchart of a method for forming a capacitor, according to certain embodiments.

FIGS. 2A-H illustrates a process flow for forming capacitor, according to certain embodiments.

FIG. 3 illustrates a flowchart of a method for forming a capacitor, according to certain embodiments.

FIGS. 4A-G illustrates a process flow for forming a capacitor, according to certain embodiments.

FIG. 5 illustrates an exemplary computer system, in which various embodiments may be implemented.

### DETAILED DESCRIPTION

Capacitors may be critical components in a power delivery network (e.g., for providing power to a processor. Capacitors may used to decouple the noise that arises from the current transients in the load. Depending on factors such as current transients, switching times, power delivery loop inductances, and other such factors, multiple capacitors may added to the power delivery network to meet a target impedance profile for a specific load condition. Important attributes of a capacitor may include high capacitance, low equivalent resistance, low inductance and other attributes. One method of increasing a capacitors performance is to increase the surface area of the electrodes of the capacitor. However, by increasing the surface area of the electrodes of the capacitor, the size of the capacitor tends to increase as well. As systems and device continue becomes smaller and smaller, the need for better-performing capacitors in small (thin) form factors becomes apparent.

Trench capacitors and multi-layer ceramic capacitors (MLCC) are commonly used capacitors. However, both types of capacitors may have limitations, particularly with the miniaturization of semiconductor devices (e.g., an advanced package). For example, MLCCs may limit integrated power delivery. An MLCC may have a relatively high parasitic loop inductance, causing unwanted disruption in the operation of the semiconductor device. MLCCs may therefore be limited to a operation frequency of less than 10 MHz to minimize the effects of the associated parasitic loop inductance. Thus, while an appropriate capacitive density may be achieved, the overall performance of the MLCC may not be adequate for all operations.

Trench capacitors may be built within a doped silicon substrate(s). To achieve the appropriate capacitive density, the doped silicon substrate(s) may include a certain thickness and aspect ratio (e.g., height and width) to achieve adequate capacitance densities. To increase the capacitance, of a trench capacitor, the overall size of the trench capacitor must be increased. The thickness of silicon and/or aspect ratio of a trench capacitor may impose major restrictions in attaining higher capacitance density in smaller packages and/or form factors. In other words, because the capacitive performance of trench capacitors is based on the overall size and micromachine vertical features, there may be a limit to a trench capacitor's ability to be used in miniaturized semiconductor devices (and other applications. Thus, there is a need in the art to provide thinner capacitors with increased capacitive density.

One solutions may be to form high surface-area electrodes for capacitors integrated into a semiconductor device (e.g., a chip, System on a Chip (SOC), advanced package, etc.). To form a high surface area electrode, a plurality of particles may be provided. The plurality of particulates may then be coated by a conducting metal, metal oxide, or other such substance. The plurality of particulates may then be coated with a dielectric material and finally, a second conducting metal layer. The plurality of particles may also be fused (either completely or partially) via sintering or another appropriate method. The particles may be at least partially pyrolyzed during the fusing process, effectively creating a metal particle coated in a dielectric material, forming a first electrode of a capacitor. The second conducting metal layer may therefore act as the second electrode of the capacitor, because it is separated from the metal particle by the dielectric layer. The resulting capacitor may be referred to as a Bryce capacitor.

The systems and processes described herein may provide advantages over the current technology by forming thinner electrodes with higher capacitive density. Unlike trench capacitors, whose capacitance scales linearly with thickness, the Bryce capacitors formed according to the processes described herein may provide more capacitance for the same thickness (i.e., a higher capacitive density). For example, if a Bryce capacitor is formed within a substrate, no additional thickness may be added to the overall system, while maintaining or increasing the capacitive performance of the device. Electronic devices (e.g., semiconductor devices) including Bryce capacitors may have a thickness of less than or about 10 μwhile providing a high capacitive density. The particle-based electrodes may be formed on glass, nickel or other inorganic substrates.

Other benefits may also be achieved by integrating Bryce capacitors. For example, Bryce capacitors may lower an electrical and/or thermal resistance to current collectors disposed between the capacitor and a processor. Bryce capacitors may also be capable of delivering higher power densities in integrated circuits (IC). With the higher capacitance provided by the Bryce capacitors, the integrated circuit may maintain low impedance, even when experiencing higher transient currents. Additionally, Bryce capacitors may be able to integrate on-chip capacitors into the package. With the higher capacitance and thinner electrodes, Bryce capacitors may be integrated within the package close to a load (e.g., a processor) and address the impedance needs over broad frequency range. By embedding Bryce capacitors in a package, a power supply in the package can perform two functions: decoupling a switching noise from loop inductance and performing voltage conversion and regulation in the package with embedded switches, drivers and controllers. Bryce capacitors may also be silicon or glass interposer and through-via compatible, able to be integrated into the interposers and related devices.

Inorganic barium titanate and silica-based particles are used to develop patterned nanoporous templates on silicon wafer substrate using screen-print, followed by stencil lift-off. Barium titanate sintering on silicon may require certain sintering temperature and cooling rates. Sintered barium titanate electrodes on silicon wafers may be obtained using the following process steps: 1. Patterned substrate preparation 2. Screen-Printing of Barium Titanate slurry 3. Sintering patterned slurry at or approximately 1100° C. for at or approximately 90 minutes. Films with good mechanical integrity may be obtained by sintering within a range of at or approximately 1050 to at or approximately 1100° C. for 60-90 min. The design of experiments have demonstrated that mechanical integrity increases with sintering temperature. An additional sintering cycle of 1100° C. for 60 minutes may be used to impart superior mechanical properties. Higher viscosity of 100,000 cps may be desired for easy deposition with printing processes. This may be achieved with mixing binders such as PVA, methyl or ethyl cellulose, or acrylates. The addition of polymer acrylate binders or Polyvinyl Alcohol (PVA) to the suspension may also help to prevent cracking from drying stresses and increase mechanical integrity. Representative powder formulations are shown in Table 1.

TABLE 1

| Silica | | | | | | |
|---|---|---|---|---|---|---|
| Slurry | Silica | Silica | Binder | Binder | | |
| volume | weight | volume | solution | weight | Binder | Powder/Binder |
| (mL) | (gm) | (cc) | volume (mL) | (gm) | Volume(cc) | ratio |
| 5 | 0.5 | 0.25 | 3 (45% methyl | 1.35 | 1.35 | 0.25/1.6 = |
| | | | cellulose of | | | 15.6% |
| | | | solids loading) | | | |
| 4 | 0.4 | 0.2 | 1 ml in 20 ml | 0.05 | 0.05 | 0.2/0.25 = 80% |
| | | | (5 wt % PVA | | | |
| | | | stock solution) | | | |

Inorganic electrode templates may be coated with nanoscale dielectric and electrode layers. The bottom electrode consists of 15-20 nm of TiN, the dielectric may include 10-15 nm of alumina, and the top electrode may include 20 nm of TiN. The tool deposition conditions are described in Table 2. TiN counter electrode films are patterned with wet chemical etch or Reactive Ion Etch (RIE) using a etch mask. The shadow etch mask may be printed onto the high-surface area porous electrodes. Etching allows to access the bottom electrode. The shadow mask film (˜10-20 micron thickness) has to be thick so that it protects the TIN top electrode on the high surface area during etching. The etch mask may be cured at 120-140° C. for 10-30 minutes.

TABLE 2

| | Chamber | | Dwell | | Precursor injection |
|---|---|---|---|---|---|
| | conditions | Pulse times | times | Purge times | conditions |
| Condition 1 | 200° C.; | TMA is 0.1 | | TMA purge: | All precursors are |
| for Alumina | Inner | sec; | | 30 seconds | at room temp: |
| 24 nm; | pressure is | H₂O is 0.1 | | H₂O purge: | 10-11 torr; |
| | 3 torr; | sec; | | 60 seconds | Inner pressure is: |
| | | | | | 3 torr. |
| Condition 2 | Holder | Dose for TMA | Dwell for | | TMA precursor |
| for Alumina | temperature | 50 ms; | TMA: | | condition: |
| 25-30 nm | is 300° C.: | Dose for H₂O | 10,000 ms; | | 7 torr at 20 sec; |
| | | is 70 ms; | Dwell for | | |
| | | | H₂O: | | |
| | | | 10,000 ms | | |
| Condition 1 | Chamber | TiCl₄ (0.3 | | TiCl₄ purge | Precursors are at |
| for TiN | Temp is | seconds) and | | is 10 sec | room temperature; |
| 24-37 nm; | 350° C. | NH₃ (3 | | NH₃ purge | Vapor pressure is |
| | | seconds) | | is 30 sec; | 11 mtorr; |
| | | | | | Inner pressure is 3 |
| | | | | | torr; |
| Condition 2 | 350° C. | Dose for TiCl₄: | RF power: | Purge is 3 | 10 torr at 20 |
| for TiN | (holder); | 100 ms; | 1 sec; | seconds; | seconds; |
| 25-30 nm | | N2 | Dwell 1: | | |

Chemical etching may be performed by inserting electrode sample in a mixture of acid etchant and Hydrogen Peroxide (H₂O₂) (PH ˜10-11) at 45-75° C. for ˜90-120 seconds followed by a cycle of DeIonized (DI) water rinse. Certain etchants may selectively etch TiN and contribute to high insulation resistance on etching topmost TiN layer. The titanium signal may be reduced from 8% to 4% as the top TiN is getting removed. After long etch times, the alumina coating may also be removed and the signal getting reduced from 5.6% to 4.5% to 0%. Reactive Ion Etch (RIE), a more controlled and slower etch process, may remove the topmost TiN layer in ˜180-210 seconds using Sulphur Hexafluoride (SF₆) and Oxygen (O₂) (10:40 sccm).

Test measurements showed the performance of the capacitors. The films that were deposited at an ALD chamber temperature of 200° C. showed good yield with insulation strength of 1Mega ohm·mm². The capacitance density for these films is ˜3.2-3.6 nF/mm². This is consistent with the expected capacitance for a dielectric thickness of 20-30 nm. With high surface area electrodes, the capacitance was of the order of 4000-6000 nF for a 25 mm² film. This shows approximately 200× enhancement in the surface area. The results are summarized in Table 3.

TABLE 3

| | | | | High | High | High |
|---|---|---|---|---|---|---|
| | | | | surface | surface | surface |
| | Planar | Planar | Planar | area | area | area |
| Measured | 4.8 | 4.12 | 11 | 4000 | 200 | 312 |
| capacitance | | | | | | |
| Lateral | 1.4 | 1.2 | 2 | 5 × 5 | 2 | 1.13 |
| footprint | | | | | | |
| Surface Area | | | | | | |
| (mm²) | | | | | | |
| Capacitance | 3.2 | 3.6 | 3.5 | 160 | 100 | 276 |
| Density | | | | | | |
| (nF/mm²) | | | | | | |

The above measurements and values therein are merely provided as example figures and values for one embodiment described herein. None of the measurements or values described above are to be construed as limiting. Other embodiments may vary in all or some of the values and measurements described above. While the description of the measurements and values above may apply to some or all of the embodiments described herein, it should be understood that the embodiments herein are not limited to the values and measurements above.

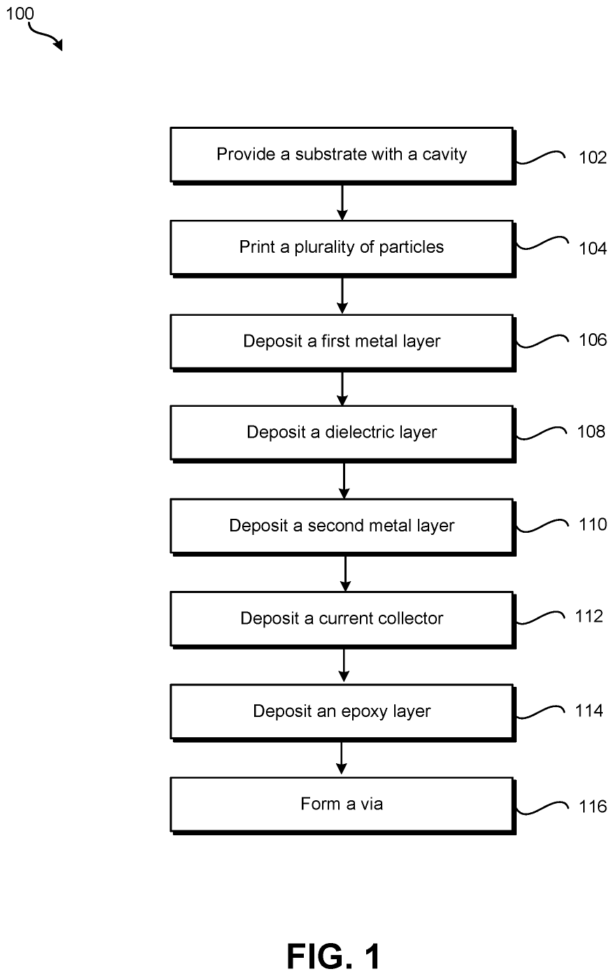

FIG. 1 illustrates a flowchart of a method 100 for forming a capacitor, according to certain embodiments. The method 100 may be performed, in whole or in part, to produce some or all of the systems and device described herein. Some or all of the steps of the method 100 may be performed in a different order than is presented and/or combined with other steps. In some embodiments, some steps of the method 100 may be skipped altogether.

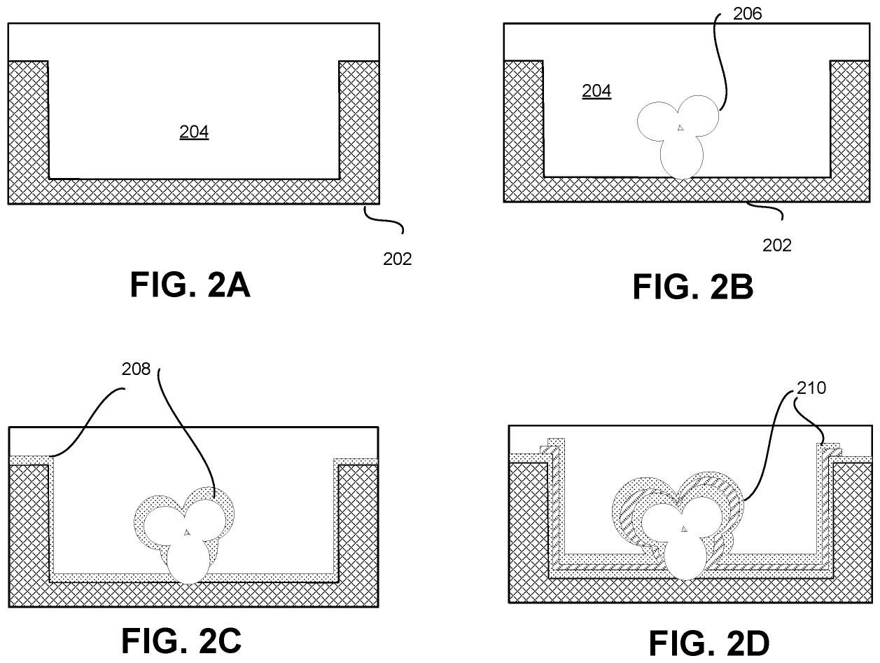

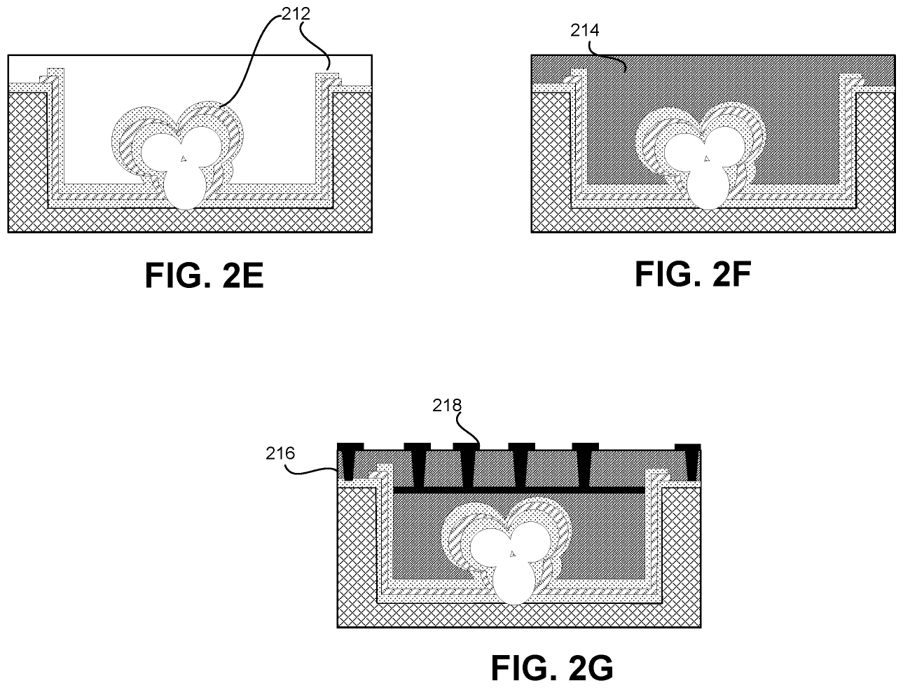

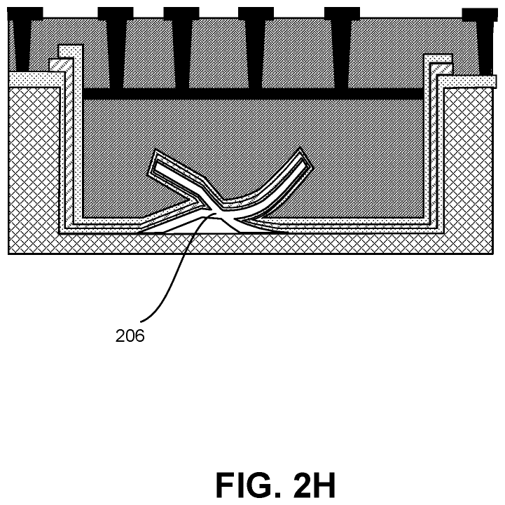

At step 102, the method 100 may include proving a substrate 202, as shown in FIG. 2A. The substrate 202 may include a cavity 204. The cavity 204 may be formed in the substrate, after the substrate 202 is formed. For example, the cavity 204 may be formed in the substrate 202 via laser ablation, etching, mechanical drilling, or any bother suitable process for removing material. In some embodiments, the substrate 202 may be manufactured to already include the cavity 204, such that no material is removed to form the cavity 204. The substrate 202 may include silicon, glass, silica, or any other suitable material. The substrate 202 may also include one or more metal films (e.g., barium titanate), deposited on a surface of the substrate 202.

At step 104, the method 100 may include printing a plurality of particles 206 on the substrate 202, as shown in FIG. 2B. In the example shown in FIG. 2B, the plurality of particles 206 may be printed in the cavity 204 of the substrate 202. The plurality of particles 206 may be printed via a screen printing process and/or a spin coating process. One or more masks (e.g., a shadow mask) may be utilized during the screen printing and/or spin coating process. The plurality of particles 206 may additionally or alternatively be formed separately from the substrate 202 and provided via one or more dispensing processes such as screen-printing, inkjet printing or other processes.

In some embodiments, silica templates may be used to form the plurality of particles 206 porous. Deionized water surface-treated silica nanoparticles (size ranging from 100 nm to 500 nm) are deposited as thin films on the substrate 202. The nanoparticles may fabricated using screen-printed square patterns after a stencil lift-off and/or via direct screen-printing. The screen printing process may utilize binders such as Polyvinyl Alcohol (PVA), methyl or ethyl cellulose, and/or acrylates. The addition of polymer acrylate binders or Polyvinyl Alcohol (PVA) to may prevent cracking from drying stresses and increase mechanical integrity.

The plurality or particles 206 may be substantially spherical and include inorganic materials such as glass, silica, ceramic, polymers, or any other suitable material. The plurality of particles 206 may be porous, allowing any materials subsequently applied to the plurality of particles 206 to at least partially penetrate an outer surface of the plurality of particles. The porosity of the plurality of particles 206 and the substantially spherical shape may provide a larger surface area per unit volume/area when compared to other types of capacitors (e.g., trench capacitors, MLCCs, etc.). The plurality of particles 206 may also include carbon- or other inorganic particle-loaded polymers. The plurality of particles 206 may completely or partially fuse to form porous electrodes at relatively low temperatures. The polymer coating of inorganic core-shell particles may allow the core-shell particles (e.g., the plurality of particles 206) to fuse at low temperatures.

In some embodiments, the plurality of particles 206 may be fiber-based instead of substantially spherical, as shown in FIG. 2H. The fiber-based plurality of particles 206 shown in FIG. 2H may be formed from electrospinning of ceramic nanofibers, polymer nanofibers, and/or other 3D porous architectures. The fiber-based particles may provide a high surface area and offer cost-savings over other approaches.

The plurality of particles 206 may be at least partially fused together via sintering or any other suitable process. The plurality of particles 206 may be fused in a regular pattern, or randomly fused together. Furthermore, while three individual particles are shown in FIGS. 2A-G, any number of particles may be included in the plurality of particles 206 (e.g., 10, 20, 100, etc.). In some embodiment, the plurality of particles 206 may not be a plurality, and instead one particle.

At step 106, the method 100 may include depositing a first metal layer 208 on the substrate 202 and the plurality of particles 206, as shown in FIG. 2C. The first metal layer 208 may be formed via sputtering, vapor layer deposition (VLD), atomic layer deposition (ALD), or any other suitable method. The first metal layer 208 may include titanium nitride, titanium, copper, cobalt, ruthenium, ruthenium oxide, titanium, oxygen, or any other suitable material. The first metal layer 208 may be deposited to a thickness of about 5 nm, about 10 nm, about 15 nm, about 20 nm, about 25 nm, about 30 nm, about 40 nm, and/or about 50 nm. The first metal layer 208 may be a conducting layer, such that the first metal layer 208 may act as an electrode in a capacitor. Depositing a dielectric directly on metal (e.g., copper or nickel) can cause interdiffusion between the dielectric and the metal and cause reliability issues. In some embodiments, a titanium nitride layer may be disposed over the first metal layer 208 and/or over the plurality of particles 206. The titanium nitride layer may act as a conduction and interdiffusion barrier, preventing interdiffusion between the dielectric and the mating surfaces.

The first metal layer 208 may at least partially coat the plurality of particles 206, For example, the first metal may 208 may cover 100% of the plurality of particles 206, or may cover about 90%, about 80%, about 70%, and/or about 60%. The first metal layer 208 may cover each particle of the plurality of particles 206 evenly, or each particle of the plurality of particles 206 may be variably coated. Because of the porous nature of the plurality of particles 206, at least some of the material of the first metal layer 208 may penetrate an outer surface of some or all of the plurality of particles 206. Thus, when acting as an electrode, the plurality of particles 206 coated in the first metal layer 208 may have a greater surface area than a capacitor taking up equal space. Thus, the capacitive density associated with a capacitor utilizing the plurality of particles 206 may be greater than other capacitor types. Areas of the cavity 204 not occupied by the plurality of particles 206 may be covered by the first metal layer 208. Areas of the substrate 202 outside of the cavity 204 may also be covered by the first metal layer 208.

At step 108, the method 100 may include depositing a dielectric layer 210 on the first metal layer 208, as shown in FIG. 2D. The dielectric layer 210 may include alumina, zirconia, barium titanate, hafnium zirconium oxide, hafnium silicate, plastics, ceramics, or any other suitable dielectric. The dielectric layer 210 may be formed via sputtering, VLD, ALD, or any other suitable method. The dielectric layer 210 may be formed to a thickness of about 2 nm, about 5 nm, about 8 nm, about 10 nm, about 12 nm, about 15 nm, and/or about 20 nm. Certain mixed component oxides may show an amorphous nature when deposited but may crystallize when treated at high temperatures in oxygenating or ozone plasma. Such films may show ferroelectric properties and lead to high permittivity. This may provide a high capacitance density. However, these films may be sensitive to temperature and voltage bias and limit long term reliability. As described herein, amorphous structures may be preferred in spite of any compromise in permittivity.

The dielectric layer 210 may be deposited on the first metal layer 208 to completely cover the plurality of particles 206 and/or other areas of the substrate 202. For example, areas of the cavity 204 not occupied by the plurality of particles 206 may be covered by the dielectric layer 210. Areas of the substrate 202 outside of the cavity 204 may also be covered by the dielectric layer 210.

At step 110, the method 100 may include depositing a second metal layer 212 on the dielectric layer 210, as shown in FIG. 2E. The second metal layer 212 may include titanium nitride, polysilicon, titanium, nickel, iron, copper, cobalt, ruthenium, ruthenium oxide, or any other suitable material. The second metal layer 212 may include the same material as the first metal layer 208 (e.g., titanium nitride) or may include different materials. The second metal layer 212 may be deposited to cover all or substantially all of the dielectric layer 210, both over the plurality of particles 206 and other areas of the substrate 202. The second metal layer 212 may be deposited to a thickness of about 5 nm, about 10 nm, about 15 nm, about 20 nm, about 25 nm, about 30 nm, about 40 nm, and/or about 50 nm.

The second metal layer 212 may serve as an electrode of a capacitor. After the deposition of the second metal layer 212, the plurality of particles 206 may be coated in conducting layers (e.g., the first and second metal layers 208 and 212) separated by a dielectric layer 210. Thus, the configuration described above may form a Bryce capacitor, providing increased capacitive performance for semiconductor and other devices.

At step 112, the method 100 may include depositing a current collector 214 on the second metal layer 212, as shown in FIG. 2F. The current collector 214 may be deposited by ALD or VLD or may be microassembled and placed on the second metal layer 212. The current collector 214 may include polysilicon, nickel, iron, copper, titanium, ruthenium, ruthenium oxide, conducting polymers (PEDOT-PSS), or any other suitable material. The current collector 214 may substantially fill the cavity 204, effectively planarizing the plurality of particles 206. The current collector 214 may therefore provide a substantially flat surface on which to further process the capacitor being manufactured via the method 100. In other words, the current collector 214 may be deposited over the both electrodes of the Bryce capacitor. The current collector 214 may also include a metal paste containing silver, graphene, and/or other suitable materials. The current collector 214 (and paste) may aid in collecting current from the Bryce capacitor and distributing the current to a power delivery network.

At step 114, the method 100 may include removing a portion of the dielectric layer 210, and the second metal layer 212 (collectively, the “layers”), as shown in FIG. 2F. The layers may be removed from one or more regions adjacent to the cavity 204. The layers may be removed via a chemical etching process, reactive ion etching process, or other suitable method. The first metal layer 208 may therefore be exposed in the one or more regions adjacent to the cavity 204. Thus, as described below, the one or more regions may form contacts for a power delivery system.

At step 116, the method 100 may include depositing an epoxy layer 216 on the Bryce capacitor, such that the Bryce capacitor is planarized, as shown in FIG. 2G. The epoxy layer 216 may include a B-type epoxy or other such material. The epoxy layer 216 may be formed via injection, ALD, VLD, lithography, or any other suitable process. The epoxy layer 216 may also be deposited such that the epoxy layer 216 can accept one or more vias.

At step 118, the method 100 may include forming a metal pathway 218, or via, on top of the epoxy layer 216 and extending through the epoxy layer 216 to be in electrical contact with one or more of the first metal layer 208 and/or the current collector 214. More than one via 218 may be formed, as is shown in FIG. 2G. For example, the via(s) 218 may be in contact with the first metal layer 208 in the regions adjacent to the cavity 204 (i.e., the contacts formed during the etching process at step 114). The via(s) 218 may also be in contact with the current collector 214. As shown in FIG. 2G, the via(s) 218 may be all be connected to each other. In other words, the first metal layer 208 and the current collector 214 may be connected to each other by the via(s) 218. In other embodiments, each of the first metal layer 208 and the current collector 214 may be electrically isolated from one another, except for the capacitive properties of the Bryce capacitor (e.g., the plurality of particles 206 and corresponding metal and dielectric layers).

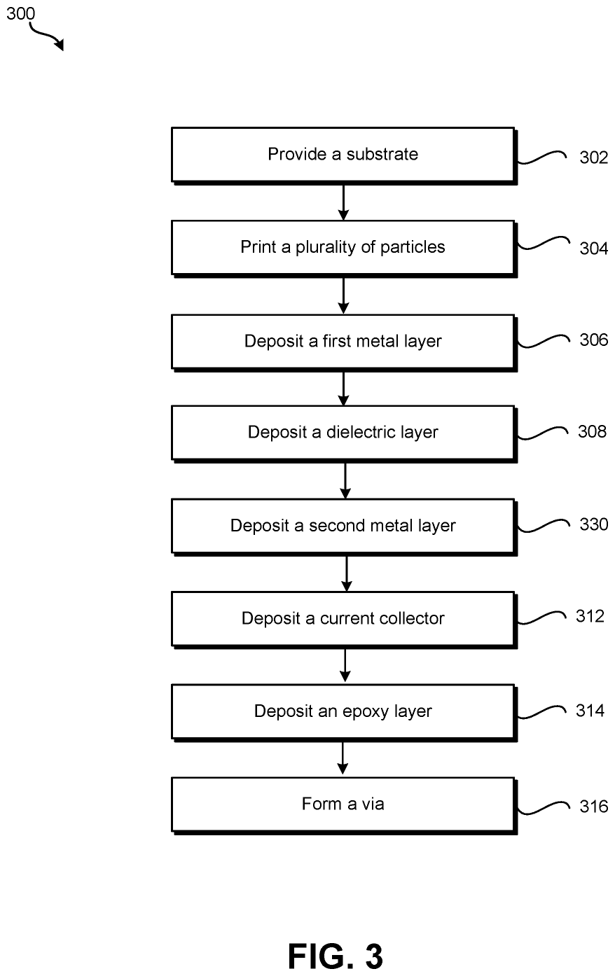

FIG. 3 illustrates a method 300 for forming a capacitor, according to certain embodiments. The method 300 may be performed, in whole or in part, to produce some or all of the systems and device described herein. Some or all of the steps of the method 300 may be performed in a different order than is presented and/or combined with other steps. In some embodiments, some steps of the method 300 may be skipped altogether.

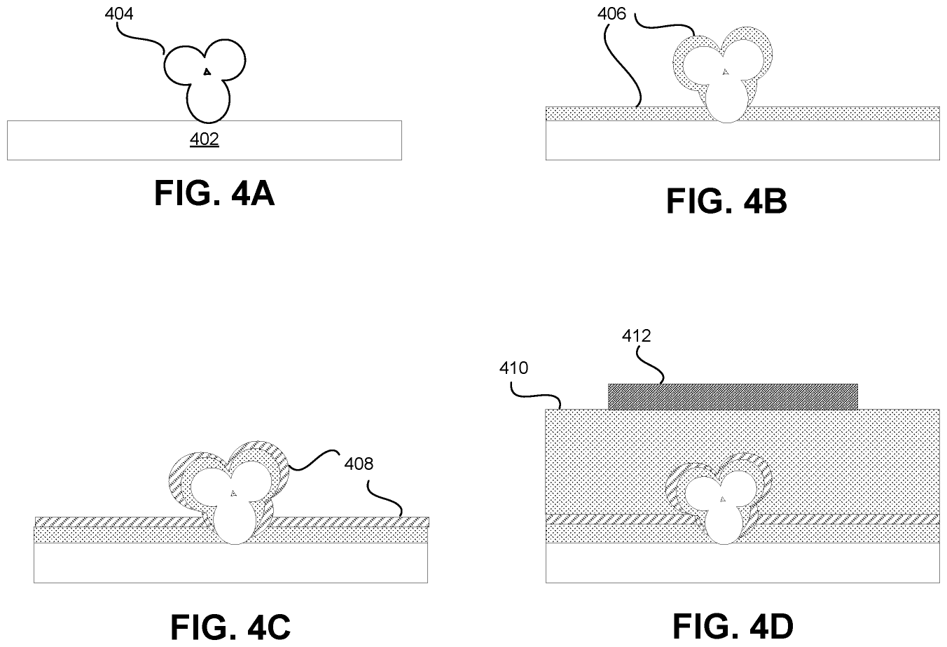

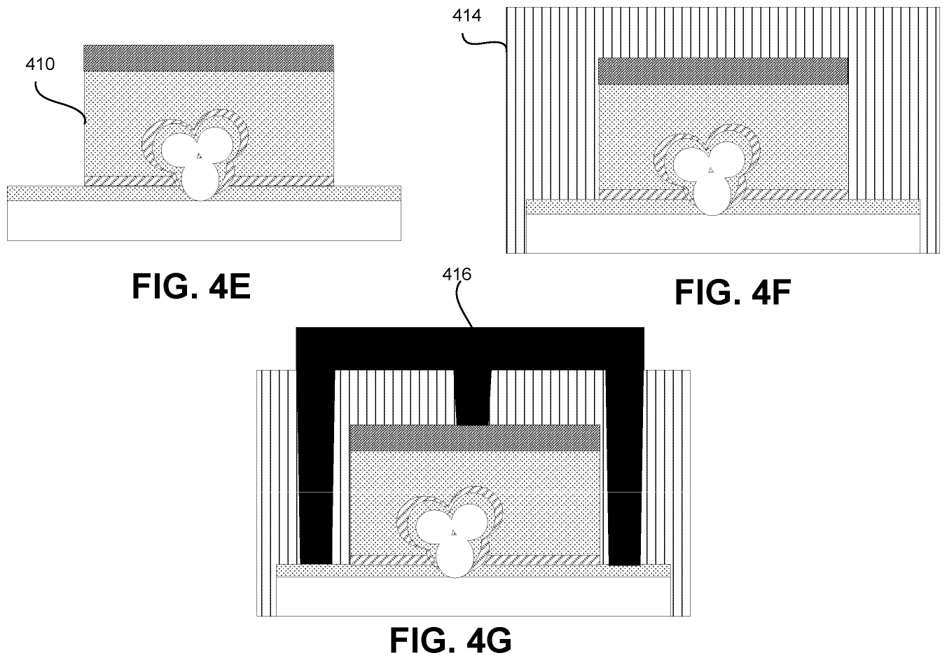

At step 302, may include providing a substrate 402, as shown in FIG. 4A. The substrate 402. The substrate 402 may include silicon, glass, silica, or any other suitable material. The substrate 402 may also include one or more metal films (e.g., barium titanate), deposited on a surface of the substrate 402.

At step 304, the method 300 may include printing a plurality of particles 404 on the substrate 402, as shown in FIG. 4A. In the example shown in FIG. 2A, the plurality of particles 404 may be printed in a particular region of the substrate 402. The plurality of particles 404 may be printed via a screen printing process and/or a spin coating process. One or more masks (e.g., a shadow mask) may be utilized during the screen printing and/or spin coating process. The plurality of particles 404 may additionally or alternatively be formed separately from the substrate 402 and provided via one or more microassembly processes.

In some embodiments, silica templates may be used to form the plurality of particles 404 porous. Deionized water surface-treated silica nanoparticles (size ranging from 100 nm to 500 nm) are deposited as thin films on the substrate 402. The nanoparticles may fabricated using screen-printed square patterns after a stencil lift-off and/or via direct screen-printing. The screen printing process may utilize binders such as Polyvinyl Alcohol (PVA), methyl or ethyl cellulose, and/or acrylates. The addition of polymer acrylate binders or Polyvinyl Alcohol (PVA) to may prevent cracking from drying stresses and increase mechanical integrity.

The plurality or particles 404 may be substantially spherical and include inorganic materials such as glass, silica, ceramic, polymers, or any other suitable material. The plurality of particles 404 may be porous, allowing any materials subsequently applied to the plurality of particles 404 to at least partially penetrate an outer surface of the plurality of particles. The porosity of the plurality of particles 404 and the substantially spherical shape may provide a larger surface area per unit volume/area when compared to other types of capacitors (e.g., trench capacitors, MLCCs, etc.). Although FIGS. 4A-4G are shown with substantially spherical particles, it should be understood that the plurality of particles 404 may include fiber-based particles, similar to those shown in FIG. 2H.

The plurality of particles 404 may be at least partially fused together via sintering or any other suitable process. The plurality of particles 404 may be fused in a regular pattern, or randomly fused together. Furthermore, while three individual particles are shown in FIGS. 2A-G, any number of particles may be included in the plurality of particles 404 (e.g., 10, 40, 100, etc.). In some embodiment, the plurality of particles 404 may not be a plurality, and instead one particle.

At step 306, the method 300 may include depositing a first metal layer 406 on the substrate 402 and the plurality of particles 404, as shown in FIG. 4B. The first metal layer 406 may be formed via sputtering, vapor layer deposition (VLD), atomic layer deposition (ALD), or any other suitable method. The first metal layer 406 may include titanium nitride, titanium, copper, cobalt, ruthenium, titanium, conducting oxides, or any other suitable material. The first metal layer 406 may be deposited to a thickness of about 5 nm, about 10 nm, about 15 nm, about 40 nm, about 25 nm, about 30 nm, about 40 nm, and/or about 50 nm. The first metal layer 406 may be a conducting layer, such that the first metal layer 406 may act as an electrode in a capacitor.

The first metal layer 406 may at least partially coat the plurality of particles 404, For example, the first metal may 408 may cover 100% of the plurality of particles 404, or may cover about 90%, about 80%, about 70%, and/or about 60%. The first metal layer 406 may cover each particle of the plurality of particles 404 evenly, or each particle of the plurality of particles 404 may be variably coated. Because of the porous nature of the plurality of particles 404, at least some of the material of the first metal layer 406 may penetrate an outer surface of some or all of the plurality of particles 404. Thus, when acting as an electrode, the plurality of particles 404 coated in the first metal layer 406 may have a greater surface area than a capacitor taking up equal space. Thus, the capacitive density associated with a capacitor utilizing the plurality of particles 404 may be greater than other capacitor types.

At step 308, the method 300 may include depositing a dielectric layer 408 on the first metal layer 406, as shown in FIG. 4C. The dielectric layer 408 may include alumina, zirconia, barium titanate, hafnium zirconium oxide, hafnium silicate, plastics, ceramics, or any other suitable dielectric. The dielectric layer 408 may be formed via sputtering, VLD, ALD, or any other suitable method. The dielectric layer 408 may be formed to a thickness of about 2 nm, about 5 nm, about 8 nm, about 10 nm, about 12 nm, about 15 nm, and/or about 40 nm. The dielectric layer 408 may be deposited on the first metal layer 406 to completely cover the plurality of particles 404 and/or other areas of the substrate 402.

At step 310, the method 300 may include depositing a second metal layer 410 on the dielectric layer 410, as shown in FIG. 4D. The second metal layer 410 may include titanium nitride, polysilicon, titanium, nickel, iron, copper, cobalt, ruthenium, ruthenium oxide, or any other suitable material. The second metal layer 410 may include the same material as the first metal layer 408 (e.g., titanium nitride) or may include different materials. The second metal layer 410 may be deposited to cover all or substantially all of the dielectric layer 410, both over the plurality of particles 404 and other areas of the substrate 402. The second metal layer 410 may be deposited to a thickness of about 5 nm, about 10 nm, about 15 nm, about 40 nm, about 25 nm, about 30 nm, about 40 nm, and/or about 50 nm. The second metal layer 410 may therefore provide a substantially flat surface on which to further process the capacitor being manufactured via the method 100.

The second metal layer 410 may serve as an electrode of a capacitor. After the deposition of the second metal layer 410, the plurality of particles 404 may be coated in conducting layers (e.g., the first and second metal layers 406 and 410) separated by a dielectric layer 408. Thus, the configuration described above may form a Bryce capacitor, providing increased capacitive performance for semiconductor and other devices.

At step 312 the method may include depositing a current collector 412 on the second metal layer 410, as shown in FIG. 4D. The current collector 412 may be deposited by ALD or VLD, or may be microassembled and placed on the second metal layer 410. The current collector 412 may include polysilicon, nickel, iron, copper, titanium, ruthenium, or any other suitable material. The current collector 412 may be deposited over the plurality of particles 404. In other words, the current collector 412 may be deposited over the both electrodes of the Bryce capacitor. The current collector 412 may also include a metal paste containing silver, graphene, and/or other suitable materials. The current collector 412 (and paste) may aid in collecting current from the Bryce capacitor and distributing the current to a power delivery network.

At step 314, the method 300 may include removing a portion of the dielectric layer 408, and the second metal layer 410 (collectively, the “layers”), as shown in FIG. 4D. The layers may be removed from one or more regions adjacent the region of the substrate 402 including the plurality of particles 404. The layers may be removed via a chemical etching process, reactive ion etching process, or other suitable method. The first metal layer 406 may therefore be exposed in the one or more regions adjacent to the plurality of particles 404. Thus, as described below, the one or more regions may form contacts for a power delivery system.

At step 316, the method 300 may include depositing an epoxy layer 414 on the Bryce capacitor, such that the Bryce capacitor is planarized, as shown in FIG. 4E. The epoxy layer 414 may include a B-type epoxy or other such material. The epoxy layer 414 may be formed via injection, ALD, VLD, lithography, or any other suitable process. The epoxy layer 416 may also be deposited such that the epoxy layer 416 can accept one or more vias.

At step 318, the method 300 may include forming a metal pathway 416, or via, on top of the epoxy layer 416 and extending through the epoxy layer 416 to be in electrical contact with one or more of the first metal layer 416 and/or the current collector 214, as shown in FIG. 4G. More than one via 416 may be formed, as is shown in FIG. 4G. For example, the via(s) 416 may be in contact with the first metal layer 406 in the regions adjacent to the plurality of particles 404 (i.e., the contacts formed during the etching process at step 314). The via(s) 218 may also be in contact with the current collector 214. As shown in FIG. 2G, the via(s) 416 may be all be connected to each other. In other words, the first metal layer 406 and the current collector 412 may be connected to each other by the via(s) 416. In other embodiments, each of the first metal layer 406 and the current collector 412 may be electrically isolated from one another, except for the capacitive properties of the Bryce capacitor (e.g., the plurality of particles 404 and corresponding metal and dielectric layers).

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user or may be done automatically by a computer system without human intervention where any determinations are made by a processor. Furthermore, some embodiments of each of the methods described herein may be implemented as a set of instructions stored on a tangible, non-transitory storage medium to form a tangible software product.

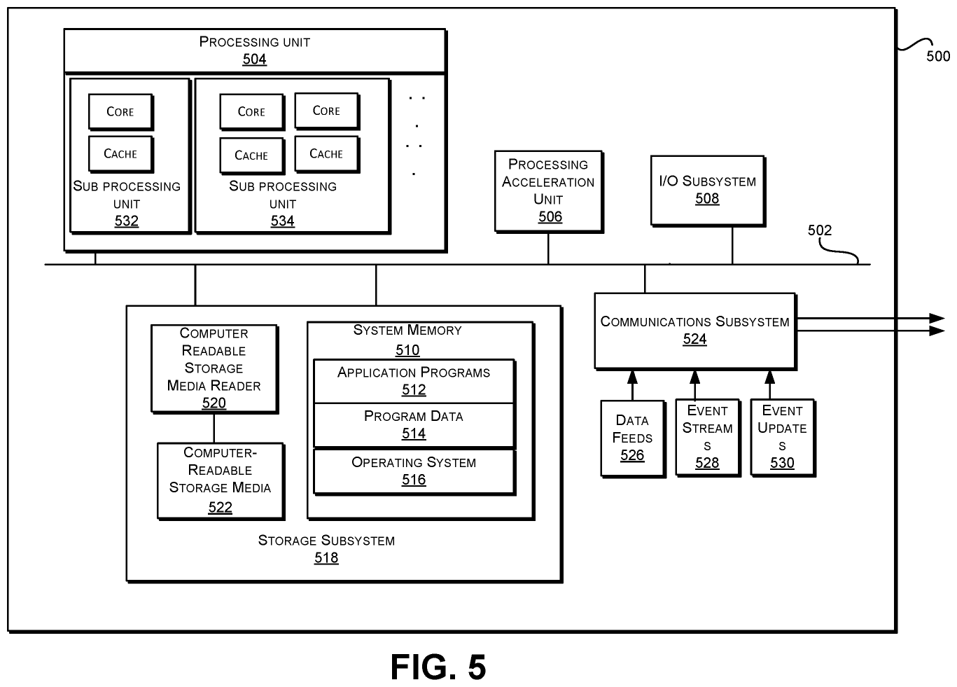

FIG. 5 illustrates an exemplary computer system 500, in which various embodiments may be implemented. The system 500 may be used to implement any of the computer systems described above. As shown in the figure, computer system 500 includes a processing unit 504 that communicates with a number of peripheral subsystems via a bus subsystem 502. These peripheral subsystems may include a processing acceleration unit 506, an I/O subsystem 508, a storage subsystem 518 and a communications subsystem 524. Storage subsystem 518 includes tangible computer-readable storage media 522 and a system memory 510.

Bus subsystem 502 provides a mechanism for letting the various components and subsystems of computer system 500 communicate with each other as intended. Although bus subsystem 502 is shown schematically as a single bus, alternative embodiments of the bus subsystem may utilize multiple buses. Bus subsystem 502 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 504, which can be implemented as one or more integrated circuits (e.g., a conventional microprocessor or microcontroller), controls the operation of computer system 500. One or more processors may be included in processing unit 504. These processors may include single core or multicore processors. In certain embodiments, processing unit 504 may be implemented as one or more independent processing units 532 and/or 534 with single or multicore processors included in each processing unit. In other embodiments, processing unit 504 may also be implemented as a quad-core processing unit formed by integrating two dual-core processors into a single chip.

In various embodiments, processing unit 504 can execute a variety of programs in response to program code and can maintain multiple concurrently executing programs or processes. At any given time, some or all of the program code to be executed can be resident in processor(s) 504 and/or in storage subsystem 518. Through suitable programming, processor(s) 504 can provide various functionalities described above. Computer system 500 may additionally include a processing acceleration unit 506, which can include a digital signal processor (DSP), a special-purpose processor, and/or the like.

I/O subsystem 508 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices that enables users to control and interact with an input device through a natural user interface using gestures and spoken commands. Additionally, user interface input devices may include voice recognition sensing devices that enable users to interact with voice recognition systems through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader, 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 500 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 500 may comprise a storage subsystem 518 that comprises software elements, shown as being currently located within a system memory 510. System memory 510 may store program instructions that are loadable and executable on processing unit 504, as well as data generated during the execution of these programs.

Depending on the configuration and type of computer system 500, system memory 510 may be volatile (such as random access memory (RAM)) and/or non-volatile (such as read-only memory (ROM), flash memory, etc.). The RAM typically contains data and/or program modules that are immediately accessible to and/or presently being operated and executed by processing unit 504. In some implementations, system memory 510 may include multiple different types of memory, such as static random access memory (SRAM) or dynamic random access memory (DRAM). In some implementations, a basic input/output system (BIOS), containing the basic routines that help to transfer information between elements within computer system 500, such as during start-up, may typically be stored in the ROM. By way of example, and not limitation, system memory 510 also illustrates application programs 512, which may include client applications, Web browsers, mid-tier applications, relational database management systems (RDBMS), etc., program data 514, and an operating system 516.

Storage subsystem 518 may also provide a tangible computer-readable storage medium for storing the basic programming and data constructs that provide the functionality of some embodiments. Software (programs, code modules, instructions) that when executed by a processor provide the functionality described above may be stored in storage subsystem 518. These software modules or instructions may be executed by processing unit 504. Storage subsystem 518 may also provide a repository for storing data used in accordance with some embodiments.

Storage subsystem 500 may also include a computer-readable storage media reader 520 that can further be connected to computer-readable storage media 522. Together and, optionally, in combination with system memory 510, computer-readable storage media 522 may comprehensively represent remote, local, fixed, and/or removable storage devices plus storage media for temporarily and/or more permanently containing, storing, transmitting, and retrieving computer-readable information.

Computer-readable storage media 522 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 500.

By way of example, computer-readable storage media 522 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD or other optical media. Computer-readable storage media 522 may include, but is not limited to, flash memory cards, universal serial bus (USB) flash drives, secure digital (SD) cards, DVD disks, digital video tape, and the like. Computer-readable storage media 522 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 500.

Communications subsystem 524 provides an interface to other computer systems and networks. Communications subsystem 524 serves as an interface for receiving data from and transmitting data to other systems from computer system 500. For example, communications subsystem 524 may enable computer system 500 to connect to one or more devices via the Internet. In some embodiments communications subsystem 524 can include radio frequency (RF) transceiver components for accessing wireless voice and/or data networks (e.g., using cellular telephone technology, advanced data network technology, such as 3G, 4G, 5G, or EDGE (enhanced data rates for global evolution), WiFi (IEEE 802.5 family standards, or other mobile communication technologies, or any combination thereof), global positioning system (GPS) receiver components, and/or other components. In some embodiments communications subsystem 524 can provide wired network connectivity (e.g., Ethernet) in addition to or instead of a wireless interface.

In some embodiments, communications subsystem 524 may also receive input communication in the form of structured and/or unstructured data feeds 526, event streams 528, event updates 530, and the like on behalf of one or more users who may use computer system 500.

By way of example, communications subsystem 524 may be configured to receive data feeds 526 in real-time from users of social networks and/or other communication services, web feeds such as Rich Site Summary (RSS) feeds, and/or real-time updates from one or more third party information sources.

Additionally, communications subsystem 524 may also be configured to receive data in the form of continuous data streams, which may include event streams 528 of real-time events and/or event updates 530, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 524 may also be configured to output the structured and/or unstructured data feeds 526, event streams 528, event updates 530, and the like to one or more databases that may be in communication with one or more streaming data source computers coupled to computer system 500.

Due to the ever-changing nature of computers and networks, the description of computer system 500 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMS, EPROMs, EEPROMs, magnetic or optical cards, flash memory, or other types of machine-readable mediums suitable for storing electronic instructions. Alternatively, the methods may be performed by a combination of hardware and software.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have been described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

What is claimed is:

1. A capacitor, comprising:
a substrate comprising a cavity;
a plurality of particles disposed within the cavity;
a first metal layer, deposited on the substrate, within the cavity, and on the plurality of particles;
a dielectric layer, deposited on the first metal layer;
a second metal layer, deposited on the dielectric layer; and
a third metal layer, deposited on the second metal layer such that the cavity is substantially filled.

2. The capacitor of claim 1, further comprising:
an epoxy layer deposited on the third metal layer; and
a via formed through the epoxy layer and in electrical contact with the first metal layer.

3. The capacitor of claim 1, where the dielectric layer comprises at least one of hafnia, zirconia, hafnium silicate, alumina, silica, and hafnium zirconium oxide.

4. The capacitor of claim 1, wherein the substrate comprises a silicon-containing material.

5. The capacitor of claim 1, wherein the plurality of particles comprises at least one of silica, silicate glass particles, and barium titanate particles.

6. The capacitor of claim 1, wherein the plurality of particles form an electrode with a diameter of about 10 microns to about 10,000 microns.

7. The capacitor of claim 1, wherein the plurality of particles are fused to form a fused electrode that is 5 microns to 500 microns in thickness.

8. The capacitor of claim 1, where the first metal layer and/or the second metal layer comprises at least one of titanium nitride, ruthenium, ruthenium oxide, tungsten, platinum, and palladium.

9. A method of forming a capacitor, comprising:
providing a substrate;
printing a plurality of particles on the substrate, the plurality of particles at least partially fused together;
depositing a first metal layer on the substrate and the plurality of particles;
depositing a dielectric layer on the first metal layer;
depositing a second metal layer on the dielectric layer, such that the plurality of particles is planarized; and
depositing a current collector layer on the second metal layer.

10. The method of claim 9, further comprising:
removing a portion of the dielectric layer and second metal layer;
depositing an epoxy, such that the capacitor is planarized; and
forming a via, such that the via is in electrical contact with at least one of the current collector layer and the first metal layer.

11. The method of claim 9, the substrate comprising a cavity wherein the plurality of particles is disposed within the cavity, the method further comprising:
removing a portion of the dielectric layer and second metal layer;
depositing an epoxy, such that the capacitor is planarized; and
forming a via such that the via is in electrical contact with at least one of current collector layer and the first metal layer.

12. The method of claim 9, wherein the plurality of particles comprise fiber-based particles.

13. The method of claim 9, wherein the current collector layer comprises a paste comprising at least one of graphene and copper.

14. The method of claim 9, wherein the current collector layer comprises a paste comprising silver.

15. The method of claim 9, wherein the plurality of particles comprises inorganic materials and a polymer coating.

16. The method of claim 9, wherein one or more of the first metal layer, the second metal layer, and the current collector layer are formed via atomic layer deposition.

17. The method of claim 9, wherein the first metal layer and the second metal layer comprise titanium nitride.

18. A capacitor, comprising:
a substrate;
a first metal layer;
a plurality of printed particles, disposed atop the first metal layer;
a dielectric layer disposed on the plurality of printed particles;
a second metal layer disposed on the dielectric layer; and
a current collector disposed on the second metal layer.

19. The capacitor of claim 18, further comprising:
an epoxy layer disposed on the second metal layer; and
a metal pathway extending from a top of the capacitor through the epoxy layer and in electrical contact with at least one of the current collector and the first metal layer.

20. The capacitor of claim 18, wherein the substrate comprises at least one of a silicon-containing material and a nickel-containing material.
